(19) United States
(12) Patent Application Publication
(10) Pub. No.: US 2010/0171134 A1
(43) Pub. Date: Jul. 8, 2010

(54) OPTICAL CONVERTER AND MANUFACTURING METHOD THEREOF AND LIGHT EMITTING DIODE

(75) Inventors: Mingda Shao, Jiang Su Province (CN); Junjie Li, Suzhou (CN); Hanyu Li, Suzhou (CN); Qiuhong Zou, Suzhou (CN); Zhiqi Wang, Suzhou (CN); Guoqing Yu, Suzhou (CN); Youjun Wang, Suzhou (CN); Wei Wang, Suzhou (CN)

Correspondence Address: WOLF GREENFIELD & SACKS, P.C., 600 ATLANTIC AVENUE, BOSTON, MA, 02210-2206, US

(73) Assignee: China Wafer Level CSP Ltd., Jiang Su Province (CN)

(21) Appl. No.: 12/482,230

(22) Filed: Jun. 10, 2009

(30) Foreign Application Priority Data
Jan. 7, 2009 (CN) 20910000394

(51) Int. Cl. G02F 1/35; H01L 33/00; B32B 17/00; C03C 27/10

(52) U.S. Cl. 257/98; 359/326; 156/102; 156/107; 257/E33.068

(57) ABSTRACT

The present invention relates to an optical converter and a manufacturing method thereof and a light emitting diode. An optical converter for a light emitting diode includes two substrates, in which, a annular first cavity wall is arranged between the two substrates, and an airtight space filled with an optical conversion substance is surrounded by the first cavity wall and the two substrates. The invention implements the encapsulation and manufacturing of the optical conversion substance for the LED. The structure and the manufacturing method according to the invention can be utilized to encapsulate an active optical conversion substance in the optical converter while avoiding the active optical conversion substance reacting to other active substance, e.g., oxygen, during manufacturing. Furthermore, the optical conversion substance is encapsulated with wafer level chip size packaging to thereby improve the efficiency of manufacturing the optical converter and reduce the cost.

### FIELD OF THE INVENTION

The present invention relates to the field of manufacturing a semiconductor device and in particular to an optical converter and a manufacturing method thereof and a light emitting diode.

### BACKGROUND OF THE INVENTION

Light Emitting Diodes (LED) have increasingly significantly improved their illumination performance indices along with the development and maturation of the technologies. Currently, a white-light LED lamp has gained a light emitting efficiency superior to that of a general incandescent lamp and approximate to that of a fluorescent lamp. Furthermore, the LED has increasingly wide applications in the illumination field due to its greatly improved luminous flux. Reference can be made to the disclosure of Chinese Patent Application No. 200810033327.3 for more information on an LED illumination device.

The traditional LED can only emit light limited to basic colors such as red, blue, yellow and green, etc., despite its energy saving. Two technical approaches have been developed in the art to obtain a white LED illumination light source. One approach is to coat yellow/red fluorescent materials over a blue power-type GaN-LED, to excite yellow/red light by a blue LED pump and mix the light to obtain white light, and the other approach is to excite coated materials with the primary colors of red/green/blue by a purple, near-ultraviolet or royal purple power-type GaN-LED pump and to mix the light to obtain white light. Both of the technical approaches have the limiting factors of the operational lifetime of the coated fluorescent materials, the loss of photons during conversion by the pump, etc., which has hindered the further improvement of device performance.

A technology of LED optical conversion with an optical conversion substance formed of nanometer quantum dots instead of a fluorescent material has become increasingly popular along with the development of the nanometer quantum dot technology. A nanometer quantum dot refers to particle cluster with extremely small sizes in three dimensions, and therefore the particles in the nanometer quantum dot may exhibit the quantum confinement effect. The quantum confinement effect refers to that when the size of material granules drops below a certain order of magnitude, e.g., from several tens of nanometers to several nanometers, the electron energy level near the metal fermi energy level changes from a quasi-continuous to a discrete energy level, and a gap between energy levels of the discrete highest occupied molecular orbital and lowest unoccupied molecular orbital where the particles constituting the nanometer quantum dot are present becomes larger, that is, the so-called widening energy gap. This effect of nanometer quantum dots is identical to what electrons and protons exhibit in atoms, and therefore the nanometer quantum dots are also referred to as “artificial atoms”.

For semiconductor nanometer quantum dots formed of an element in the family of II-VIB or III-VB, electrons and holes are restricted in domain by quantum, a continuous energy band becomes a structure of discrete energy levels with the feature of molecules, and the nanometer quantum dots can emit light upon excitation. Excitation light of nanometer quantum dots has a very wide range of wavelengths, and nanometer quantum dots with different colors can be excited by light at the same wavelength. For example, red and green nanometer quantum dots are excited by a blue light LED to emit white light. Therefore, in the art, an LED optical converter has come to be formed of nanometer quantum dots instead of the existing fluorescent materials. Reference can be made to China Taiwan Patent Application No. 95107997 with Publication No. 287887 for more information on a technology of forming a white light LED from nanometer quantum dots.

Due to the small size of a nanometer quantum dot and a large ratio of the number of atoms on the surface to the total number of atoms, i.e., large specific surface area, the nanometer quantum dot is highly chemically active, extremely instable and prone to combining with other atoms, and hence is more chemically active than in a normal status.

Therefore, nanometer quantum dots have to be isolated from a relatively active substance such as oxygen and the like in a LED optical converter made of nanometer quantum dots, and a process of manufacturing the LED optical converter is essentially a process of encapsulating nanometer quantum dots in an inert material. Thus, the LED optical converter containing the nanometer quantum dots can be manufactured with semiconductor packaging technique. Furthermore, the nanometer quantum dots also have to be isolated from an active substance such as an adhesive and the like during the manufacture of the optical converter.

Furthermore, an LED optical converter is manufactured in the prior art with a one-by-one packaging method, thereby resulting in inefficiency. No application has been available for the use of Wafer Level Chip Size Packaging (WLCSP) technology to manufacture any LED optical converter. Wafer level chip size packaging technology is referred to as the technology that packaging and testing are performed at a whole wafer and then the packaged wafer is singulated into individual finished chips with the same size in X and Y directions as original dies. The chips packaged with wafer level chip size packaging are highly miniaturized in size, and the cost of the chips is significantly reduced with the decreasing size of the chips and the increasing size of the wafer. An application of wafer level chip size packaging to manufacturing of an LED optical converter can be anticipated for a considerably improved efficiency and reduced cost of manufacturing.

### SUMMARY OF THE INVENTION

A technical problem to be solved with the invention is how to encapsulate an active optical conversion substance in an airtight environment to form an optical converter for an LED.

To solve the above problem, the invention provides an optical converter for a light emitting diode, which includes two substrates, in which an annular first cavity wall is arranged between the two substrates, and an airtight space filled with an optical conversion substance is surrounded by the first cavity wall and the two substrates.

Optionally, the optical conversion substance contains nanometer quantum dots.

Optionally, the first cavity wall and one of the substrates are integral.

Optionally, an adhesion layer is arranged between the first cavity wall and the other substrate.

Optionally, the material of the adhesion layer is the optical conversion substance.

Optionally, the optical conversion substance is a silica gel in which nanometer quantum dots are distributed evenly.

Optionally, the silica gel has a viscosity of 5000 cp to 40000 cp.

Optionally, the first cavity wall includes an upper cavity wall connected with one of the substrates and a lower cavity wall connected with the other substrate, which are superposed over one another.

Optionally, an adhesion layer is arranged between the upper cavity wall and the lower cavity wall.

Optionally, the first cavity wall is with a thickness of 40 μm to 200 μm.

Optionally, an annular second cavity wall enclosing the first cavity wall is further arranged between the two substrates.

Optionally, an adhesion layer is arranged between the second cavity wall and one of the substrates.

Optionally, the first cavity wall is in the shape of a circular ring, and the second cavity wall is in the shape of a square ring.

Optionally, the spacing between the first cavity wall and the second cavity wall is smaller than 200 μm.

Optionally, the spacing between the first cavity wall and the second cavity wall is 80 μm to 100 μm.

Optionally, the space between the first cavity wall and the second cavity wall is vacuum or filled with a rare gas or nitrogen.

Optionally, the second cavity wall is with a thickness of 40 μm to 200 μm.

Optionally, the two substrates are transparent substrates.

Optionally, a material of which the two substrates are made includes glass or plastic.

According to another aspect of the invention, there is provided a method of manufacturing an optical converter for a light emitting diode, which includes the steps of: forming a first cavity wall on a first substrate; filling an optical conversion substance within a space surrounded by the first cavity wall; and laminating the first cavity wall with a second substrate and the first substrate to seal the optical conversion substance.

Optionally, the optical conversion substance contains nanometer quantum dots.

Optionally, a way of forming the first cavity wall on the first substrate is to etch the first substrate to form the first cavity wall.

Optionally, a way of forming the first cavity wall on the first substrate is to bond the first cavity wall on the first substrate.

Optionally, the optical conversion substance with which the space surrounded by the first cavity wall is filled is with a height above a thickness of the first cavity wall; the lamination process extrudes the optical conversion substance to overflow between the second substrate and the first cavity wall; and the sealing is performed by bonding the second substrate and the first cavity wall with the optical conversion substance overflowing between the second substrate and the first cavity wall.

Optionally, the optical conversion substance is a silica gel in which nanometer quantum dots are distributed evenly.

Optionally, the silica gel has a viscosity of 5000 cp to 40000 cp.

Optionally, the number of the first cavity wall formed on the first substrate is larger than two.

Optionally, there are further included the steps of: forming a second cavity wall on the second substrate; forming an adhesion layer on the side of the second cavity wall away from the second substrate; and bonding the second cavity wall and the side of the first substrate on which the first cavity wall is arranged, so that the first cavity wall is enclosed by the second cavity wall.

Optionally, a way of forming the second cavity wall on the second substrate is to etching the second substrate to form the second cavity wall.

Optionally, a way of forming the second cavity wall on the second substrate is to bonding the second cavity wall on the second substrate.

Optionally, the number of the first cavity wall formed on the first substrate is larger than two.

Optionally, the first cavity wall is in the shape of a circular ring, and the second cavity wall is in the shape of a square ring.

Optionally, the spacing between the first cavity wall and the second cavity wall is 80 μm to 100 μm.

Optionally, the lamination is performed in an atmosphere of vacuum or a rare gas or nitrogen.

Optionally, the first substrate and the second substrate are transparent substrates.

Optionally, a material of which the first substrate and the second substrate are made includes glass or plastic.

According to a further aspect of the invention, there is provided a method of manufacturing an optical converter for a light emitting diode, which includes the steps of: forming a lower cavity wall on a first substrate; filling an optical conversion substance within a space surrounded by the lower cavity wall; forming an upper cavity wall corresponding to the lower cavity wall on a second substrate; and laminating the upper cavity wall and the lower cavity wall to seal the optical conversion substance.

Optionally, the optical conversion substance contains nanometer quantum dots.

Optionally, a way of forming the lower cavity wall on the first substrate is to etch the first substrate to form the lower cavity wall.

Optionally, a way of forming the lower cavity wall is formed on the first substrate is to bond the lower cavity wall on the first substrate.

Optionally, a way of forming the upper cavity wall is formed on the second substrate is to etch the second substrate to form the upper cavity wall.

Optionally, a way of forming the upper cavity wall is formed on the second substrate is to bond the upper cavity wall on the second substrate.

Optionally, there is further included the step of forming an adhesion layer on the side of the upper cavity wall away from the second substrate.

Optionally, the number of the lower cavity wall formed on the first substrate is larger than two.

Optionally, the number of the upper cavity wall is the same as that of the lower cavity wall.

Optionally, there are further included the steps of: forming a second cavity wall enclosing the upper cavity wall on the second substrate and with a thickness equal to the sum of those of the upper cavity wall and the lower cavity wall; forming an adhesion layer on the side of the second cavity wall away from the second substrate; and bonding the second cavity wall and the side of the first substrate on which the lower cavity wall is arranged, so that the lower cavity wall is enclosed by the second cavity wall.

Optionally, a way of forming the second cavity wall on the second substrate is to etch the second substrate to form the second cavity wall.

Optionally, a way of forming the second cavity wall on the second substrate is to bond the second cavity wall on the second substrate.

Optionally, the number of the second cavity wall formed on the second substrate is the same as that of the upper cavity wall.

Optionally, the spacing between the upper cavity wall and the second cavity wall is 80 μm to 100 μm.

Optionally, there are further included the steps of: forming a second cavity wall enclosing the lower cavity wall on the first substrate and with a thickness equal to the sum of those of the upper cavity wall and the lower cavity wall; forming an adhesion layer on the side of the second cavity wall away from the first substrate; and bonding the second cavity wall and the side of the second substrate on which the upper cavity wall is arranged, so that the upper cavity wall is enclosed by the second cavity wall.

Optionally, the number of the second cavity wall formed on the first substrate is the same as that of the lower cavity wall.

Optionally, a way of forming the second cavity wall on the first substrate is to etch the first substrate to form the second cavity wall.

Optionally, a way of forming the second cavity wall on the first substrate is to bond the second cavity wall on the first substrate.

Optionally, the spacing between the lower cavity wall and the second cavity wall is 80 μm to 100 μm.

Optionally, the upper cavity wall and the lower cavity wall are in the shape of a circular ring, and the second cavity wall is in the shape of a square ring.

Optionally, the lamination is performed in an atmosphere of vacuum or a rare gas or nitrogen.

Optionally, the first substrate and the second substrate are transparent substrates

Optionally, a material of which the first substrate and the second substrate are made includes glass or plastic.

According to still another aspect, there is provided a light emitting diode including any preceding optical converter and a PN junction, in which the PN junction is arranged on the side of either of the two substrates of the optical converter away from the other substrate.

The invention implements the encapsulation and manufacturing of the optical conversion substance for the LED.

The structure and the manufacturing method according to the invention can be utilized to encapsulate an active optical conversion substance in the optical converter while avoiding the active optical conversion substance reacting to other active substance, e.g., oxygen, during manufacturing.

Furthermore, the optical conversion substance is encapsulated with wafer level chip size packaging to thereby improve the efficiency of manufacturing the optical converter and reduce the cost.

### BRIEF DESCRIPTION OF THE DRAWINGS

FIG. 1 is a schematic sectional view of an optical converter according to an embodiment of the invention;

FIG. 2 is a top view of the optical converter illustrated in FIG. 1;

FIG. 3 is a flow chart of a method of manufacturing the optical converter illustrated in FIG. 1;

FIG. 4 to FIG. 7 are schematic diagrams of manufacturing the optical converter in the flow illustrated in FIG. 3;

FIG. 8 is a schematic sectional view of an optical converter according to another embodiment of the invention;

FIG. 9 is a top view of the optical converter illustrated in FIG. 8;

FIG. 10 is a flow chart of a method of manufacturing the optical converter illustrated in FIG. 8;

FIG. 11 to FIG. 14 are schematic diagrams of manufacturing the optical converter in the flow illustrated in FIG. 10;

FIG. 15 is a schematic sectional view of an optical converter according to an embodiment of the invention;

FIG. 16 is a top view of the optical converter illustrated in FIG. 15;

FIG. 17 is a flow chart of a method of manufacturing the optical converter illustrated in FIG. 15;

FIG. 18 to FIG. 21 are schematic diagrams of manufacturing the optical converter in the flow illustrated in FIG. 17;

FIG. 22 is a schematic sectional view of an optical converter according to still another embodiment of the invention; and

FIG. 23 is a schematic sectional view of an optical converter according to a further embodiment of the invention.

### DETAILED DESCRIPTION OF THE INVENTION

### The First Embodiment

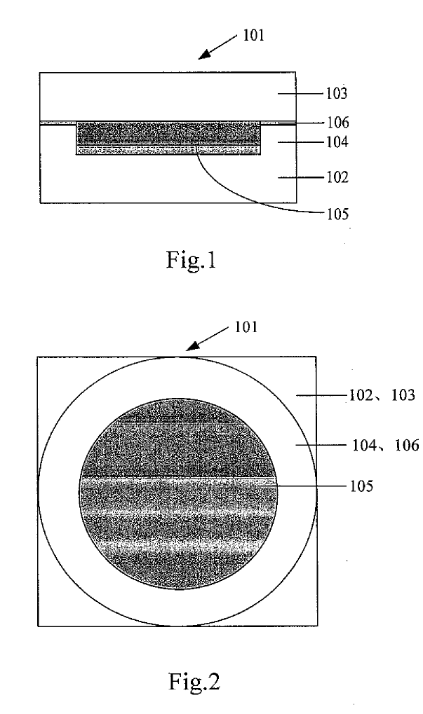

There is provided in this embodiment an optical converter 101 for an LED, a sectional view of which is as illustrated in FIG. 1 and a top view of which is as illustrated in FIG. 2. Referring to FIG. 1 and FIG. 2 together, the optical converter 101 includes a first substrate 102, a second substrate 103 and an annular first cavity wall 104 sandwiched between the first substrate 102 and the second substrate 103. An airtight space in which an optical conversion substance 105 is sealed is surrounded by the first cavity wall 104 together with the first substrate 102 and the second substrate 103.

The optical conversion substance 105 sealed in the optical converter 101 can be various, e.g., photoluminescence-type fluorescent materials or nanometer quantum dots, and since some of the photoluminescence-type fluorescent materials and the nanometer quantum dots are relatively active materials and hence prone to reaction to other substances, they need to be sealed for use. The optical converter 101 according to this embodiment can achieve this purpose. The nanometer quantum dots are typically not used separately but can be dispersed in an inert material, e.g., silica gel, and thus can be conveniently filled during manufacturing without influence upon the performance thereof.

As illustrated in FIG. 2, the first cavity wall 104 is in the shape of a closed circular ring in the top view. Naturally, the circular ring is merely illustrative, and since the first cavity wall 104 serves to cooperate with the first substrate 102 and the second substrate 103 to form a airtight cavity, as long as the first cavity wall 104 is in the shape of a closed ring in the top view, e.g., a square ring, the object of this embodiment is also can be attained. The first cavity wall 104 can be with a thickness of approximately 40 μm to 200 μm. The thickness as referred to here can be defined as a distance from the top surface of the cavity wall to the substrate which is etched to form the cavity wall, and this definition will apply throughout the detailed descriptions of the invention.

The first substrate 102 and the second substrate 103 can be in the shape of a square as illustrated in FIG. 2 or in the shape, e.g., of a circle, accommodating the annular first cavity wall 104. The first substrate 102 and the second substrate 103 can be shaped identically or differently as required for the shape of the finally formed LED.

Since the first substrate 102 and the second substrate 103 serve to seal the optical conversion substance 105, at least parts of the first substrate 102 and the second substrate 103 corresponding to the optical conversion substance 105 are transparent. Since the first substrate 102 and the second substrate 103 may contact with the optical conversion substance, and some optical conversion substances, e.g., those containing nanometer quantum dots, are relatively active substances, the first substrate 102 and the second substrate 103 shall be made of a chemically inert material. A preferred light-transmissive and inert material of which the first substrate 102 and the second substrate 103 are made may be silicate glass or a plastic material with a high light transmittance, for example.

The first cavity wall 104 and the first substrate 102 are integral without adhesion layer therebetween, and an adhesion layer 106 is arranged between the first cavity wall 104 and the second substrate 103 to bond them together. The adhesion layer 106 is made of a material which does not react to the optical conversion substance 105. Since some optical conversion substance 105 may have a certain viscosity, for example, when the optical conversion substance 105 is a silica gel with a viscosity of 5000 cp to 40000 cp in which nanometer quantum dots are distributed evenly, the optical conversion substance 105 can be used directly as the adhesion layer 106.

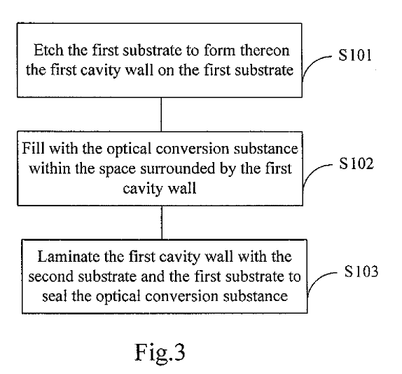

A method for forming the above optical converter 101 includes the following steps as illustrated in FIG. 3.

Step S101 is to etch the first substrate to form the first cavity wall on the first substrate;

Step S102 is to fill the optical conversion substance within the space surrounded by the first cavity wall;

Step 103 is to laminate the first cavity wall with the second substrate and the first substrate to seal the optical conversion substance.

The above method will be detailed below with reference to the drawings.

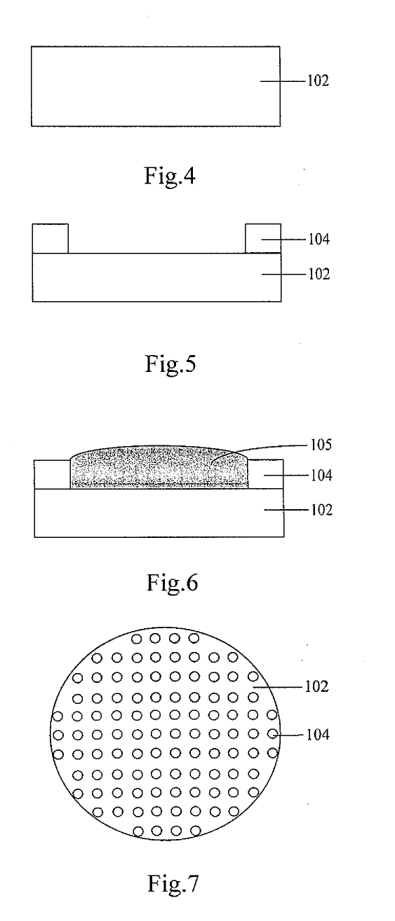

As illustrated in FIG. 4, firstly the first substrate 101 made of transparent glass is prepared with a thickness of approximately 1000 μm. Then, the first substrate 102 is spin-coated with a photo-resist and etched by exposure, development and etching processes to form the first cavity wall 104 with a thickness of approximately 40 μm to 200 μm on the first substrate 102, thereby forming the structure as illustrated in FIG. 5 and thus finishing the step S101.

Then, the step S102 is executed in which the space surrounded by the first cavity wall 104 is filled with the optical conversion substance 105, for example, through filling the optical conversion substance 105 within the space surrounded by the first cavity wall 104 by a dispensing machine or otherwise, e.g., silk screen printing or steel plate printing. The optical conversion substance 105 filled with here is a silica gel with a viscosity of 5000 cp to 40000 cp in which nanometer quantum dots are distributed evenly and with a height above the thickness of the first cavity wall 104, thereby forming the structure as illustrated in FIG. 6.

Then the step S103 is executed in which the first cavity wall 104 is laminated with the second substrate 103 and first substrate 102 to seal the optical conversion substance 105. Since the optical conversion substance 105 with which the space surrounded by the first cavity wall 104 is filled is of a height above that the thickness of the first cavity wall 104 in the step S102, the lamination process in the step S103 may extrude the optical conversion substance 105 to overflow between the second substrate 103 and the first cavity wall 104. Furthermore due to the high viscosity up to 5000 cp to 40000 cp of the optical conversion substance 105, the optical conversion substance 105 overflowing between the second substrate 103 and the first cavity wall 104 bond the second substrate 103 and the first cavity wall 104 while lamination is in progress. Finally, the optical conversion substance 105 overflowing between the second substrate 103 and the first cavity wall 104 bond the first cavity wall 104 and the second substrate 103 together completely at the end of lamination to thereby seal the optical conversion substance 105 within the space surrounded by the first cavity wall 104.

Since the optical conversion substance 105 is active, the above manufacturing process can be conducted in an atmosphere of vacuum or rare gas or nitrogen.

Naturally, in order to improve the efficiency of manufacturing the optical converter 101, the first substrate 102 of a wafer level size can be etched to form thereon a plurality of first cavity walls 104 in the step S101, thereby forming the structure as illustrated in FIG. 7. Correspondingly, the second substrate 103 also adopts a glass substrate of the same size. Thus, a batch of optical converters 101 can be packaged and manufactured in one time to accomplish an application of wafer level chip size packaging to manufacturing of the optical converter 101 of the LED, thereby significantly improving the efficiency of manufacturing and reducing cost.

### The Second Embodiment

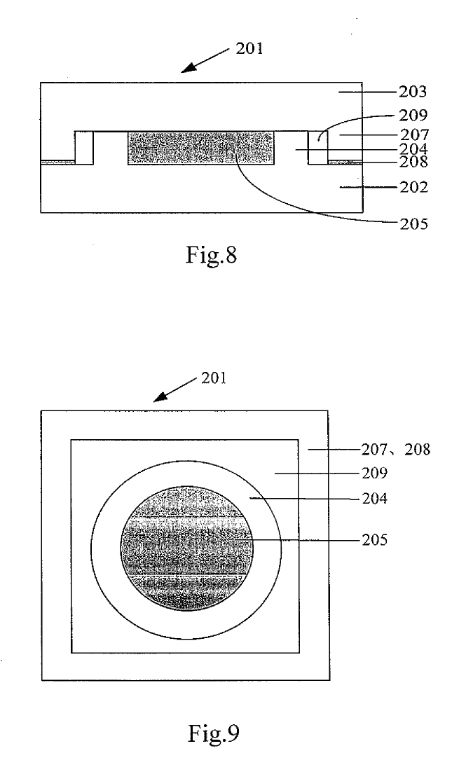

There is provided in this embodiment an optical converter 201 for an LED, a sectional view of which is as illustrated in FIG. 8 and a top view of which is as illustrated in FIG. 9. Referring to FIG. 8 and FIG. 9 together, the optical converter 201 includes a first substrate 202 and a second substrate 203. The first substrate 202 further includes an annular first cavity wall 204, and the second substrate 203 further includes an annular second cavity wall 207. The annular first cavity wall 204 and the annular second cavity wall 207 are sandwiched between the first substrate 202 and the second substrate 203. An airtight space in which an optical conversion substance 205 is sealed is surrounded by the first cavity wall 204 together with the first substrate 202 and the second substrate 203. An airtight space in which the first cavity wall 204 and the optical conversion substance 205 are sealed is surrounded by the second cavity wall 207 together with the first substrate 202 and the second substrate 203.

There is a distance of approximately 80 μm to 100 μm between the first cavity wall 204 and the second cavity wall 207 to thereby form a buffer space 209 isolated from the outside. The buffer space 209 is formed for the purpose of accommodating the optical conversion substance 205 overflowing from the first cavity wall 204. The buffer space 209 is vacuumized or filled with a gas which does not react to the optical conversion substance 205, e.g., a rare gas or nitrogen.

Like the first embodiment, the optical conversion substance 205 sealed in the optical converter 201 can be various with a silica gel in which nanometer quantum dots are dispersed being preferred.

As illustrated in FIG. 9, the first cavity wall 204 is in the shape of a closed circular ring in the top view, and the second cavity wall 207 is in the shape of a closed square ring enclosing the first cavity wall in the top view. Naturally, the circular and square rings here are merely illustrative, and since the first cavity wall 204 serves to cooperate with the first substrate 202 and the second substrate 203 to form the airtight cavity, and the second cavity wall 207 serves to cooperate with the first substrate 202, the second substrate 203 and the first cavity wall 204 to form the buffer space 209 isolated from the outside, the first cavity wall 204 and the second cavity wall 207 also can be in another shape in the top view. The first cavity wall 204 can be with a thickness of approximately 40 μm to 200 μm. The second cavity wall 207 can be with the same or substantially the same thickness as that of the first cavity wall 204.

The first substrate 202 and the second substrate 203 can be in the shape of a square as illustrated in FIG. 2 or in the shape, e.g., of a square, accommodating the annular second cavity wall 207. Naturally like the first embodiment, the first substrate 202 and the second substrate 203 can be shaped identically or differently as required for the shape of the finally formed LED.

At least parts of the first substrate 202 and the second substrate 203 corresponding to the optical conversion substance 205 are transparent, and the first substrate 202 and the second substrate 203 shall be made of a chemically inert material, for example, silicate glass or PMMA.

It is different from the first embodiment that no adhesion layer is arranged between the first cavity wall 204 and the second substrate 203, but an adhesion layer 208 is arranged between the second cavity wall 207 and the first substrate 202 to seal the space surrounded by the second cavity wall 207 and the first and second substrates 202 and 203. Since the adhesion layer 208 will not contact the optical conversion substance in the second embodiment, the material of the adhesion layer 208 will not be limited in the second embodiment.

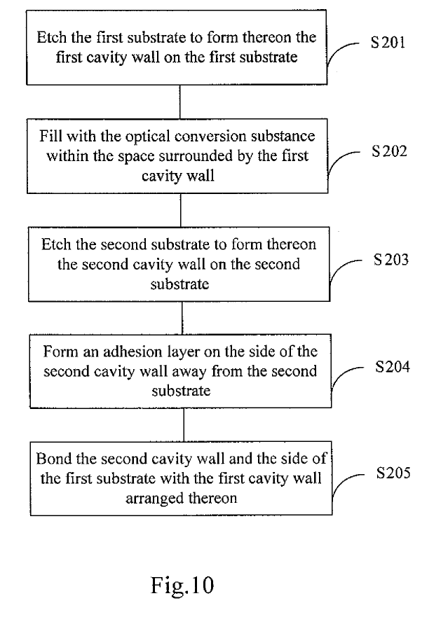

A method for forming the above optical converter 201 includes the following steps as illustrated in FIG. 10.

Step S201 is to etch the first substrate to form the first cavity wall on the first substrate.

Step S202 is to fill the optical conversion substance within the space surrounded by the first cavity wall.

Step S203 is to etch the second substrate to form the second cavity wall on the second substrate.

Step S204 is to form the adhesion layer on the side of the second cavity wall away from the second substrate.

Step S205 is to bond the second cavity wall and the side of the first substrate on which the first cavity wall is arranged to make the first cavity wall to be enclosed by the second cavity wall, and to laminate the first cavity wall with the second substrate and the first substrate to seal the optical conversion substance.

The above method will be detailed below with reference to the drawings.

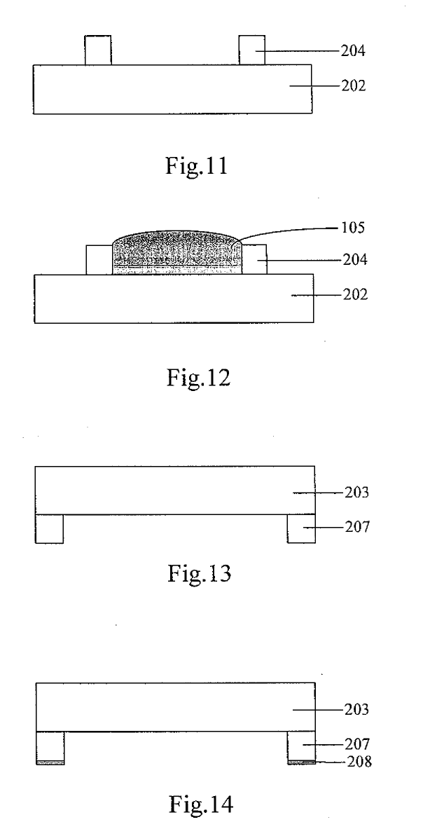

Firstly, the first substrate 202 made of transparent glass is prepared with a thickness of approximately 1000 μm. Then, the first substrate 202 is spin-coated with a photo-resist and etched by exposure, development and etching processes to form the first cavity wall 204 on the first substrate 202, thereby forming the structure as illustrated in FIG. 11.

Then, the step S202 is executed in which the space surrounded by the first cavity wall 204 is filled with the optical conversion substance 205, like the first embodiment, for example, through filling the optical conversion substance 205 within the space surrounded by the first cavity wall 204 by a dispensing machine or otherwise, e.g., silk screen printing or steel plate printing. The optical conversion substance 205 filled with here may be a silica gel in which nanometer quantum dots are distributed evenly and with a height at least equal to the thickness of the first cavity wall 204.

Next, the second substrate 203 made of transparent glass is prepared with a thickness of approximately 1000 μm. Then, the second substrate 203 is spin-coated with a photo-resist and etched by exposure, development and etching processes to form the second cavity wall 207 on the second substrate 203, thereby forming the structure as illustrated in FIG. 13 and thus finishing the step S203. The space surrounded by the second cavity wall 207 shall accommodate at least the entire first cavity wall 204, so that the second cavity wall 207 can enclose the first cavity wall 204 in subsequent steps. Furthermore, the second cavity wall 207 shall also be with a thickness equivalent to that of the first cavity wall 204.

Next, the step S204 is executed in which the adhesion layer 208 is formed on the side of the second cavity wall 207 away from the second substrate 203 as illustrated in FIG. 14. Since the adhesion layer 208 formed here will not contact the optical conversion substance 205, its material will not be further limited, and the adhesion layer 208 can be attached on the side of the second cavity wall 207 away from the second substrate 203 directly with an adhesive rolling process.

Then, the step S205 is executed in which the first cavity wall 204 is enclosed in the second cavity wall 207, and the second cavity wall 207 and the side of the first substrate on which the first cavity wall 204 is arranged are bonded with the adhesion layer 208. During the process of bonding, the first cavity wall 207 is laminated with the second substrate 203 and the first substrate 202 to seal the optical conversion substance, thereby finally forming the structure as illustrated in FIG. 8.

In the step S202, the optical conversion substance 205 with which the first cavity wall 204 is filled shall be with a height at least equal to the thickness of the first cavity wall 204 because the optical conversion substance 205 has a certain viscosity and surface tension. Therefore the optical conversion substance 205 may not take up the entire space surrounded by the first cavity wall 204 during being filled with dispensing process or the like. Therefore, the optical conversion substance 205 can be laminated with the second substrate 203 and the first substrate 202 to fill up the space surrounded by the first cavity wall 204. Since the filled optical conversion substance 205 may be with a volume larger than that of the space surrounded by the first cavity wall 204, a part of the optical conversion substance 205 may overflow from the space surrounded by the first cavity wall 204. At this time, the buffer space 209 between the first cavity wall 204 and the second cavity wall 207 can serve to accommodate the overflowing optical conversion substance 205.

Also since the optical conversion substance 205 is active, the above manufacturing process can be conducted in an atmosphere of vacuum or rare gas or nitrogen. Accordingly, the buffer space 209 between the first cavity wall 204 and the second cavity wall 207 will also be vacuum or filled with a rare gas or nitrogen at the end of manufacturing.

Naturally, in order to improve the efficiency of manufacturing the optical converter 201, the first substrate 202 of a wafer level size can be etched to form thereon a plurality of first cavity walls 204 in the step S201. Correspondingly, the second substrate 203 also adopts a glass substrate of the same size and is etched to form thereon a plurality of second cavity walls 207 corresponding to the first cavity walls 204 in the step S203. Thus, a batch of optical converters 201 can be packaged and manufactured in one time to accomplish an application of WLCSP to manufacturing of the optical converter 201 of the LED.

### The Third Embodiment

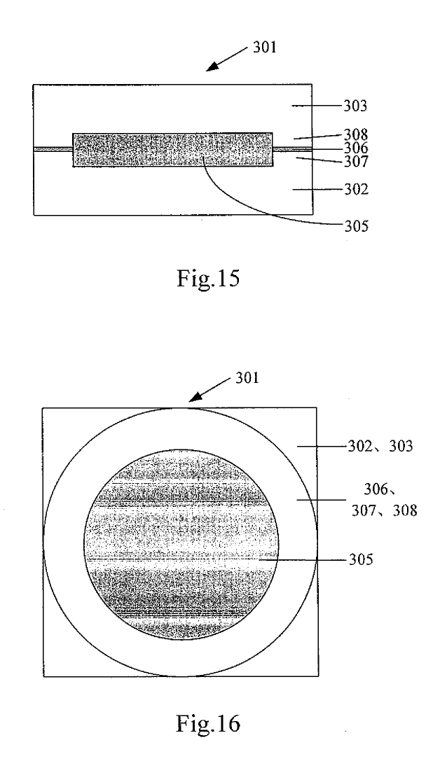

There is provided in this embodiment an optical converter 301 for an LED, a sectional view of which is as illustrated in FIG. 15 and a top view of which is as illustrated in FIG. 16. Referring to FIG. 15 and FIG. 16 together, the optical converter 301 includes a first substrate 302 and a second substrate 303. The first substrate 302 further includes an annular lower cavity wall 307, and the second substrate 303 further includes an annular upper cavity wall 308 in a shape corresponding to that of the lower cavity wall 307. The lower cavity wall 307 and the upper cavity wall 308 are engaged, so that an airtight space in which an optical conversion substance 305 is sealed is surrounded by the lower cavity wall 307, the upper cavity wall 308, the first substrate 302 and the second substrate 303.

As mentioned in the first and second embodiments, the optical conversion substance 305 sealed in the optical converter 301 can be various, e.g., photoluminescence-type fluorescent materials or nanometer quantum dots.

The lower cavity wall 307 and the upper cavity wall 308 can be in the shape of a closed circular ring in the top view and with a thickness of 40 μm to 200 μm. Widths of the lower cavity wall 307 and the upper cavity wall 308 may be identical or different and naturally preferably identical. The width of a cavity wall as referred to here is defined as a distance of the inner ring to the outer ring of the cavity wall, and this definition will apply hereinafter. The inner rings of the lower cavity wall 307 and the upper cavity wall 308 may or may not coincide and preferably coincide. Similarly, the outer rings of the lower cavity wall 307 and the upper cavity wall 308 may or may not coincide and preferably coincide.

As mentioned in the first and second embodiments, the first substrate 302 and the second substrate 303 can be in the shape of a square or circle, for example. The first substrate 302 and the second substrate 303 can be shaped identically or differently as required for the shape of the finally formed LED.

An adhesion layer 306 is arranged between the lower cavity wall 307 and the upper cavity wall 308 to bond them together. Since the adhesion layer 306 will not contact the active optical conversion substance 305 during manufacturing of this embodiment, the material of which the adhesion layer 306 is made will not be further limited, for example, be limited to an adhesive material which does not react to the optical conversion substance 305.

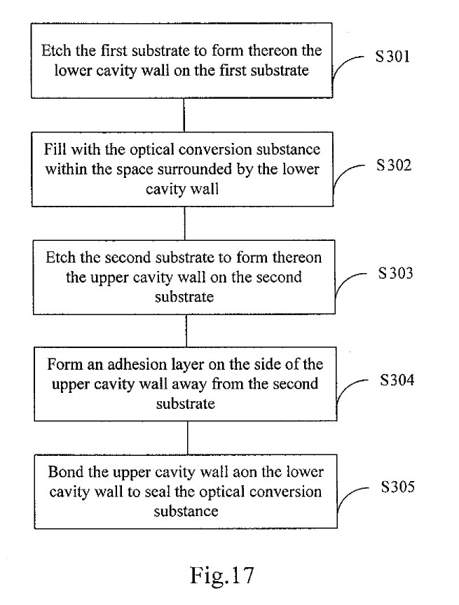

A method for forming the above optical converter 301 includes the following steps as illustrated in FIG. 17.

Step S301 is to etch the first substrate to form the lower cavity wall on the first substrate.

Step S302 is to fill the optical conversion substance within the space surrounded by the lower cavity wall.

Step S303 is to etch the second substrate to form the upper cavity wall on the second substrate.

Step S304 is to form the adhesion layer on the side of the upper cavity wall away from the second substrate.

Step S305 is to bond the upper cavity wall and the lower cavity wall to seal the optical conversion substance.

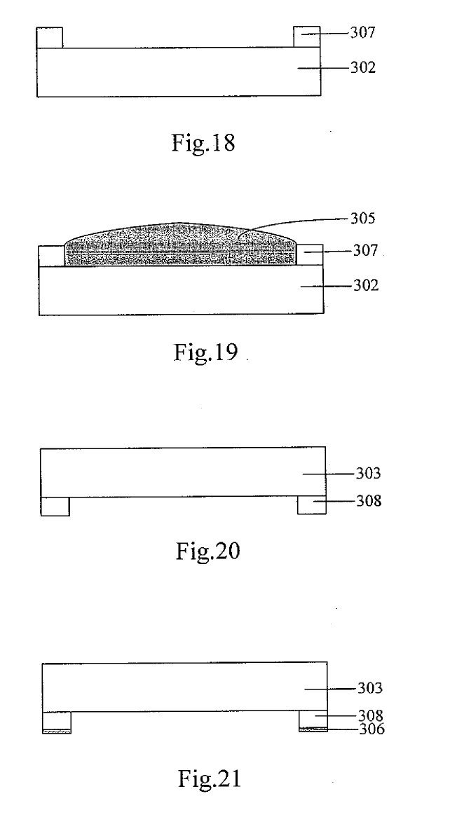

As illustrated in FIG. 18, firstly the step S301 is executed to etch the first substrate 302 to form the annular lower cavity wall 307 on the first substrate 302, and the specific step of etching the first substrate 302 is the same as in the foregoing embodiments and detailed descriptions thereof will be omitted here.

Then, the step S302 is executed in which the space surrounded by the lower cavity wall 307 is filled with the optical conversion substance 305. Like the foregoing embodiments, the filled optical conversion substance 305 shall be with a height above the thickness of the lower cavity wall 307, thereby forming the structure as illustrated in FIG. 19.

Next, the step S303 is executed in which the second substrate 303 is etched to form the annular upper cavity wall 308, thereby forming the structure as illustrated in FIG. 20. The upper cavity wall 308 is in the shape corresponding to that of the lower cavity wall 307 but may be with a width different from that of the lower cavity wall 307. That is to say, the inner ring of the annular upper cavity wall 308 shall be smaller than the outer ring of the annular lower cavity wall 307, and correspondingly the inner ring of the annular lower cavity wall 307 shall be smaller than the outer ring of the annular upper cavity wall 308.

Then, the step S304 is executed in which the adhesion layer 306 is formed on the side of the upper cavity wall 308 away from the second substrate 303, thereby forming the structure as illustrated in FIG. 21. Since the adhesion layer 306 formed here will not contact the optical conversion substance 305, its material will not be further limited, and the adhesion layer 306 can be attached on the side of the upper cavity wall 308 away from the second substrate 303 directly with an adhesive rolling process.

Finally, the step S305 is executed in which the upper cavity wall 308 and the lower cavity wall 307 are bonded correspondingly to seal the optical conversion substance. The corresponding bonding as referred to here means that the inner ring of the annular upper cavity wall 308 falls inside the outer ring of the annular lower cavity wall 307 and the inner ring of the annular lower cavity wall 307 also falls inside the outer ring of the annular upper cavity wall 308. Such bonding forms the airtight space in which the optical conversion substance 305 is sealed is surrounded by the lower cavity wall 307, the upper cavity wall 308, the first substrate 302 and the second substrate 303.

Also since the optical conversion substance 305 is active, the above manufacturing process can be conducted in an atmosphere of vacuum or rare gas or nitrogen.

Like the foregoing embodiments, in order to improve the efficiency of manufacturing the optical converter 301, the first substrate 302 of a wafer level size can be etched to form thereon a plurality of lower cavity walls 307 in the step S301. Correspondingly, the second substrate 303 also adopts a glass substrate of the same size and is etched to form thereon a plurality of upper cavity walls 308 corresponding to the lower cavity walls 307 in the step S303. Thus, a batch of optical converters 301 can be packaged and manufactured in one time to accomplish an application of WLCSP to manufacturing of the optical converter 301 of the LED.

### The Fourth Embodiment

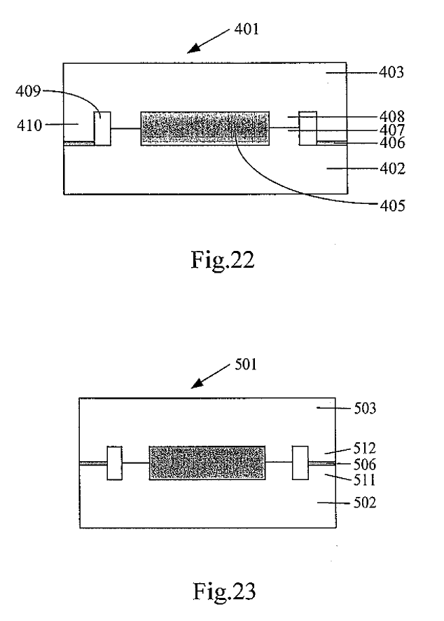

Following the idea of the third embodiment, the first cavity wall 204 in the second embodiment can be divided into two upper and lower cavity walls made respectively on the first substrate and the second substrate, thereby forming the structure as illustrated in FIG. 22, in which, 401 denotes the optical converter, 402 denotes the first substrate, 403 denotes the second substrate, 406 denotes the adhesion layer, 407 denotes the lower cavity wall constituting the first cavity wall, 408 denotes the upper cavity wall constituting the first cavity wall, 409 denotes a buffer space formed of the spacing between the lower cavity wall 407 and upper cavity wall 408 engaged with each other and the second cavity wall 410, the buffer space 409 functions in the same way as the buffer space 209 in the second embodiment, and 410 denotes the second cavity wall.

Naturally in this embodiment, the second cavity wall 410 can be formed from etching on the second substrate 403 or the first substrate 402. The object of this embodiment can be attained as long as the thickness of the second cavity wall 410 is the same or substantially the same as the sum of those of the lower cavity wall 407 and the upper cavity wall 408.

### The Fifth Embodiment

Following the idea of the third embodiment, the second cavity wall 410 in the fourth embodiment can further be divided into a second lower cavity wall 511 formed from etching on the first substrate 502 and a second upper cavity wall 512 formed from etching on the second substrate 503. An adhesion layer 506 for bonding the two upper and lower substrates is arranged between the second lower cavity wall 511 and the second upper cavity wall 512, thereby forming the structure of an optical converter 501 as illustrated in FIG. 23.

The manufacturing procedure is conducted firstly for the first substrate and then for the second substrate in the foregoing five embodiments. However, the scope of the invention will not be limited thereto, and the manufacturing steps for the first substrate and those for the second substrate can be reversed without influencing the implement of the invention.

Furthermore, the first cavity wall, the second cavity wall, the upper cavity wall, the lower cavity wall and the like are formed by etching the substrates in the foregoing five embodiments. However, the scope of the invention will not be limited thereto, and the cavity walls also can be formed on the substrates by bonding the annular cavity walls on the corresponding substrates.

A PN junction for light emission of the LED can further be arranged on the side of the first substrate of the optical converter away from the second substrate or the side of the second substrate away from the first substrate in the above embodiments to thereby form the general structure of the LED. Naturally, devices, e.g., light reflection plates, for improving the performance of the LED, can further be arranged on other sides of the PN junction than the side thereof close to the substrate to thereby form a complete LED with superior performance, and these devices are well known to those skilled in the art and detailed descriptions thereof will be omitted here.

The preferred embodiments of the invention have been disclosed as above but are not intended to limit the claims of the invention. Any skilled in the art may make possible variations and modifications without departing from the spirit and scope of the invention, and accordingly the scope of the protection of the invention shall be defined in accordance with the claims of the invention.

1. An optical converter for a light emitting diode, comprising two substrates, wherein an annular first cavity wall is arranged between the two substrates, and an airtight space filled with an optical conversion substance is surrounded by the first cavity wall and the two substrates.

2. The optical converter for a light emitting diode according to claim 1, wherein the optical conversion substance contains nanometer quantum dots.

3. The optical converter for a light emitting diode according to claim 1, wherein the first cavity wall and one of the substrates are integral.

4. The optical converter for a light emitting diode according to claim 3, wherein an adhesion layer is arranged between the first cavity wall and the other substrate.

5. The optical converter for a light emitting diode according to claim 4, wherein a material of the adhesion layer is the optical conversion substance.

6. The optical converter for a light emitting diode according to claim 1 or 5, wherein the optical conversion substance is a silica gel in which nanometer quantum dots are distributed evenly.

7. The optical converter for a light emitting diode according to claim 6, wherein the silica gel has a viscosity of 5000 cp to 40000 cp.

8. The optical converter for a light emitting diode according to claim 1, wherein the first cavity wall comprises an upper cavity wall connected with one of the substrates and a lower cavity wall connected with the other substrate, which are superposed over one another.

9. The optical converter for a light emitting diode according to claim 8, wherein an adhesion layer is arranged between the upper cavity wall and the lower cavity wall.

10. The optical converter for a light emitting diode according to claim 1 or 8, wherein the first cavity wall is with a thickness of 40 μm to 200 μm.

11. The optical converter for a light emitting diode according to claim 1 or 8, wherein a annular second cavity wall enclosing the first cavity wall is further arranged between the two substrates.

12. The optical converter for a light emitting diode according to claim 11, wherein an adhesion layer is arranged between the second cavity wall and one of the substrates.

13. The optical converter for a light emitting diode according to claim 11, wherein the first cavity wall is in a shape of a circular ring, and the second cavity wall is in a shape of a square ring.

14. The optical converter for a light emitting diode according to claim 11, wherein a spacing between the first cavity wall and the second cavity wall is smaller than 200 μm.

15. The optical converter for a light emitting diode according to claim 11, wherein the spacing between the first cavity wall and the second cavity wall is 80 μm to 100 μm.

16. The optical converter for a light emitting diode according to claim 11, wherein a space between the first cavity wall and the second cavity wall is vacuum or filled with a rare gas or nitrogen.

17. The optical converter for a light emitting diode according to claim 11, wherein the second cavity wall is with a thickness of 40 μm to 200 μm.

18. The optical converter for a light emitting diode according to claim 1, wherein an adhesion layer is arranged between the first cavity wall and each of the two substrates.

19. The optical converter for a light emitting diode according to claim 1, wherein a material of which the two substrates are made comprises glass or plastic.

20. A method of manufacturing an optical converter for a light emitting diode, comprising the steps of:
forming a first cavity wall on a first substrate;
filling an optical conversion substance within a space surrounded by the first cavity wall; and
laminating the first cavity wall with a second substrate and the first substrate to seal the optical conversion substance.

21. The method of manufacturing an optical converter for a light emitting diode according to claim 20, wherein the optical conversion substance contains nanometer quantum dots.

22. The method of manufacturing an optical converter for a light emitting diode according to claim 20, wherein a way of forming the first cavity wall on the first substrate is to etch the first substrate to form the first cavity wall.

23. The method of manufacturing an optical converter for a light emitting diode according to claim 20, wherein a way of forming the first cavity wall on the first substrate is to bond the first cavity wall on the first substrate.

24. The method of manufacturing an optical converter for a light emitting diode according to claim 20, wherein:
the optical conversion substance with which the space surrounded by the first cavity wall is filled is with a height above a thickness of the first cavity wall;
the lamination process extrudes the optical conversion substance to overflow between the second substrate and the first cavity wall; and
the sealing is performed by bonding the second substrate and the first cavity wall with the optical conversion substance overflowing between the second substrate and the first cavity wall.

25. The method of manufacturing an optical converter for a light emitting diode according to claim 20 or 24, wherein the optical conversion substance is a silica gel in which nanometer quantum dots are distributed evenly.

26. The method of manufacturing an optical converter for a light emitting diode according to claim 25, wherein the silica gel has a viscosity of 5000 cp to 40000 cp.

27. The method of manufacturing an optical converter for a light emitting diode according to claim 20, wherein the number of the first cavity wall formed on the first substrate is larger than two.

28. The method of manufacturing an optical converter for a light emitting diode according to claim 20, further comprising the steps of:
forming a second cavity wall on the second substrate;
forming an adhesion layer on a side of the second cavity wall away from the second substrate; and
bonding the second cavity wall and a side of the first substrate on which the first cavity wall is arranged, so that the first cavity wall is enclosed by the second cavity wall.

29. The method of manufacturing an optical converter for a light emitting diode according to claim 28, wherein a way of forming the second cavity wall on the second substrate is to etch the second substrate to form the second cavity wall.

30. The method of manufacturing an optical converter for a light emitting diode according to claim 28, wherein a way of forming the second cavity wall on the second substrate is to bond the second cavity wall on the second substrate.

31. The method of manufacturing an optical converter for a light emitting diode according to claim 28, wherein the number of the first cavity wall formed on the first substrate is larger than two.

32. The method of manufacturing an optical converter for a light emitting diode according to claim 28, wherein the first cavity wall is in a shape of a circular ring, and the second cavity wall is in a shape of a square ring.

33. The method of manufacturing an optical converter for a light emitting diode according to claim 28, wherein a spacing between the first cavity wall and the second cavity wall is 80 μm to 100 μm.

34. The method of manufacturing an optical converter for a light emitting diode according to claim 28, wherein the lamination is performed in an atmosphere of vacuum or a rare gas or nitrogen.

35. The method of manufacturing an optical converter for a light emitting diode according to claim 20, wherein the first substrate and the second substrate are transparent substrates.

36. The method of manufacturing an optical converter for a light emitting diode according to claim 20, wherein a material of which the first substrate and the second substrate are made comprises glass.

37. A method of manufacturing an optical converter for a light emitting diode, comprising the steps of:
forming a lower cavity wall on a first substrate;
filling an optical conversion substance within a space surrounded by the lower cavity wall;
forming an upper cavity wall corresponding to the lower cavity wall on a second substrate; and
laminating the upper cavity wall and the lower cavity wall to seal the optical conversion substance.

38. The method of manufacturing an optical converter for a light emitting diode according to claim 37, wherein the optical conversion substance contains nanometer quantum dots.

39. The method of manufacturing an optical converter for a light emitting diode according to claim 37, wherein a way of forming the lower cavity wall on the first substrate is to etch the first substrate to form the lower cavity wall.

40. The method of manufacturing an optical converter for a light emitting diode according to claim 37, wherein a way of forming the lower cavity wall on the first substrate is to bond the lower cavity wall on the first substrate.

41. The method of manufacturing an optical converter for a light emitting diode according to claim 37, wherein a way of forming the upper cavity wall on the second substrate is to etch the second substrate to form the upper cavity wall.

42. The method of manufacturing an optical converter for a light emitting diode according to claim 37, wherein a way of forming the upper cavity wall on the second substrate is to bond the upper cavity wall on the second substrate.

43. The method of manufacturing an optical converter for a light emitting diode according to claim 37, further comprising the step of forming an adhesion layer on a side of the upper cavity wall away from the second substrate.

44. The method of manufacturing an optical converter for a light emitting diode according to claim 37, wherein the number of the lower cavity wall formed on the first substrate is larger than two.

45. The method of manufacturing an optical converter for a light emitting diode according to claim 44, wherein the number of the upper cavity wall is the same as that of the lower cavity wall.

46. The method of manufacturing an optical converter for a light emitting diode according to claim 37, further comprising the steps of:
forming a second cavity wall enclosing the upper cavity wall on the second substrate and with a thickness equal to a sum of those of the upper cavity wall and the lower cavity wall;
forming an adhesion layer on a side of the second cavity wall away from the second substrate; and
bonding the second cavity wall and a side of the first substrate on which the lower cavity wall is arranged, so that the lower cavity wall is enclosed by the second cavity wall.

47. The method of manufacturing an optical converter for a light emitting diode according to claim 46, wherein a way of forming the second cavity wall on the second substrate is to etch the second substrate to form the second cavity wall.

48. The method of manufacturing an optical converter for a light emitting diode according to claim 46, wherein a way of forming the second cavity wall on the second substrate is to bond the second cavity wall on the second substrate.

49. The method of manufacturing an optical converter for a light emitting diode according to claim 46, wherein the number of the second cavity wall formed on the second substrate is the same as that of the upper cavity wall.

50. The method of manufacturing an optical converter for a light emitting diode according to claim 46, wherein a spacing between the upper cavity wall and the second cavity wall is 80 μm to 100 μm.

51. The method of manufacturing an optical converter for a light emitting diode according to claim 37, further comprising the steps of:
forming a second cavity wall enclosing the lower cavity wall on the first substrate and with a thickness equal to a sum of those of the upper cavity wall and the lower cavity wall;
forming an adhesion layer on a side of the second cavity wall away from the first substrate; and
bonding the second cavity wall and a side of the second substrate on which the upper cavity wall is arranged, so that the upper cavity wall is enclosed by the second cavity wall.

52. The method of manufacturing an optical converter for a light emitting diode according to claim 51, wherein the number of the second cavity wall formed on the first substrate is the same as that of the lower cavity wall.

53. The method of manufacturing an optical converter for a light emitting diode according to claim 51, wherein a way of forming the second cavity wall on the first substrate is to etch the first substrate to form the second cavity wall.

54. The method of manufacturing an optical converter for a light emitting diode according to claim 51, wherein a way of forming the second cavity wall on the first substrate is to bond the second cavity wall on the first substrate.

55. The method of manufacturing an optical converter for a light emitting diode according to claim 51, wherein a spacing between the lower cavity wall and the second cavity wall is 80 μm to 100 μm.

56. The method of manufacturing an optical converter for a light emitting diode according to claim 46 or 51, wherein the upper cavity wall and the lower cavity wall are in a shape of a circular ring, and the second cavity wall is in a shape of a square ring.

57. The method of manufacturing an optical converter for a light emitting diode according to claim 37, wherein the lamination is performed in an atmosphere of vacuum or a rare gas or nitrogen.

58. The method of manufacturing an optical converter for a light emitting diode according to claim 37, wherein the first substrate and the second substrate are transparent substrates.

59. The method of manufacturing an optical converter for a light emitting diode according to claim 37, wherein a material of which the first substrate and the second substrate are made comprises glass or plastic.

60. A light emitting diode comprising the optical converter according to claim 1 and a PN junction, wherein the PN junction is arranged on a side of either of the two substrates of the optical converter away from the other substrate.
